(19) United States
(12) Patent Application Publication
(10) Pub. No.: US 2023/0108268 A1
(43) Pub. Date: Apr. 6, 2023

(54) BATTERY ENERGY STORAGE SYSTEM AND OPERATING METHOD THEREOF

(71) Applicant: INSTITUTE FOR INFORMATION INDUSTRY, Taipei City (TW)

(72) Inventors: Shang Wen LUAN, Taipei City (TW); Jui Ming WU, Taipei City (TW); Chun Chun HUANG, Taipei City (TW); Jing Jun YANG, Taipei City (TW)

(73) Assignee: INSTITUTE FOR INFORMATION INDUSTRY, Taipei City (TW)

(21) Appl. No.: 17/575,364

(22) Filed: Jan. 13, 2022

(30) Foreign Application Priority Data
Sep. 24, 2021 (TW) 110135575

(51) Int. Cl. H01M 10/42; H01M 10/44; H01M 10/48; H02J 7/00; G01R 31/396

(52) U.S. Cl. CPC H01M 10/425; H01M 10/441; H01M 10/482; H02J 7/0048; G01R 31/396; H01M 2010/4271

(57) ABSTRACT

An operating method for a Battery Energy Storage System (BESS) is provided. The BESS includes a processor and a plurality of energy storage units coupled in parallel, wherein each energy storage unit includes a Power Conservation System (PCS) and a battery module. The operating method includes performing following steps by the processor: obtaining a dedicated operation power of the BESS; calculating a remaining operation period of each energy storage unit according to a maximum operation power of each PCS and a remaining power quantity of each battery module; determining an operational order corresponding to the plurality of energy storage units according to the remaining operation period of the plurality of energy storage units and the dedicated operation power of the BESS; and controlling an operation of each energy storage unit according to the operational order.

### CROSS-REFERENCE TO RELATED APPLICATIONS

This non-provisional application claims priority under 35 U.S.C. § 119(a) on Patent Application No(s). 110135575 filed in Taiwan, ROC on Sep. 24, 2021, the entire contents of which are hereby incorporated by reference.

### BACKGROUND

### 1. Technical Field

The present disclosure relates to a Battery Energy Storage System (BESS), and more particular to a BESS capable of providing the electricity with the maximal power and operation method thereof.

### 2. Related Art

In order to balance the demand of carbon reduction and industrial development, more and more renewable energy sources, such as solar power, wind power, are utilized in the existing electricity grid. However, renewable energy cannot be completely controlled by humans. When the ratio of the electricity provided by renewable energy to the overall electricity provided by the electricity grid increases, it is easy to cause shortage in the supplied power of the electricity grid, thereby increasing the risk of power tripping.

The fast charging and discharging characteristics of the BESS can provide a variety of services for the electricity grid, effectively reducing the impact when the renewable energy is integrated into the electricity grid. However, improper operation methods will seriously affect the efficiency and service life of the BESS. Therefore, there is a dire need for a control method for optimizing the input and output of the BESS.

### SUMMARY

In view of this, the present disclosure proposes a Battery Energy Storage System (BESS) and operation method thereof. Under the condition that the total input and output of the energy storage system remain unchanged, the present disclosure may perform a fast and appropriate power distribution to ensure that the BESS can have maximized input and output.

According to an embodiment of the present disclosure, an operation method of BESS applicable to a BESS, wherein the BESS comprises a plurality of energy storage units connected in parallel and a processor, each of the plurality of energy storage units comprises a Power Conversion System (PCS) and a battery module, and the operation method comprises following operations performed by the processor: obtaining at least one of a specified operation power and a specified State of Charge (SOC) of the BESS; calculating an available operation period of each of the plurality of the energy storage units according to a maximal operation power of the PCS of each of the plurality of energy storage units and a remaining power of each of the battery module of each of the plurality of energy storage units; determining an operational order corresponding to the plurality of energy storage units at least according to the available operation period of each of the plurality of energy storage units and the specified operation power of the BESS; and controlling an operation of each of the plurality of energy storage units according to the operational order.

According to an embodiment of the present disclosure, a BESS comprising: an input interface configured to obtain a specified operation power of the BESS; a plurality of energy storage units connected in parallel, wherein each of the plurality of energy storage unit comprises a PCS and a battery module, and the PCS is electrically connected to the battery module for charging the battery module or discharging the battery module; and a processor electrically connected to the input interface and the plurality of energy storage unit, wherein the processor is configured to perform following operations: calculating an available operation period of each of the plurality of the energy storage units according to a maximal operation power of each of the plurality of PCS and a remaining power of each of the plurality of battery module; determining an operational order corresponding to the plurality of energy storage units at least according to the available operation period of each of the plurality of energy storage units and the specified operation power of the BESS; and controlling an operation of each of the plurality of energy storage units according to the operational order.

In view of the above, the present disclosure provides a BESS and an operation method thereof. Through the optimization of the input/output power configuration, the present disclosure avoids the following situation: some energy storage units discharge all the energy or be fully charged in advance since each battery module has a different SOC, this situation will reduce the overall maximal input/output capacity of the BESS. The present disclosure allows the BESS to extend the duration of maximal power input/output, and to meet the requirements of the specified operation power or the specified SOC.

### BRIEF DESCRIPTION OF THE DRAWINGS

The present disclosure will become more fully understood from the detailed description given herein below and the accompanying drawings which are given by way of illustration only and thus are not limitative of the present disclosure and wherein:

FIG. 1 is a block diagram of a BESS according to an embodiment of the present disclosure;

FIG. 2 is a flow chart of an operation method of the BESS according to an embodiment of the present disclosure;

FIG. 3 is a detailed flow chart of a step in FIG. 2; and

FIG. 4 is a detailed flow chart of another step in FIG. 2.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present invention. The following embodiments further illustrate various aspects of the present invention, but are not meant to limit the scope of the present invention.

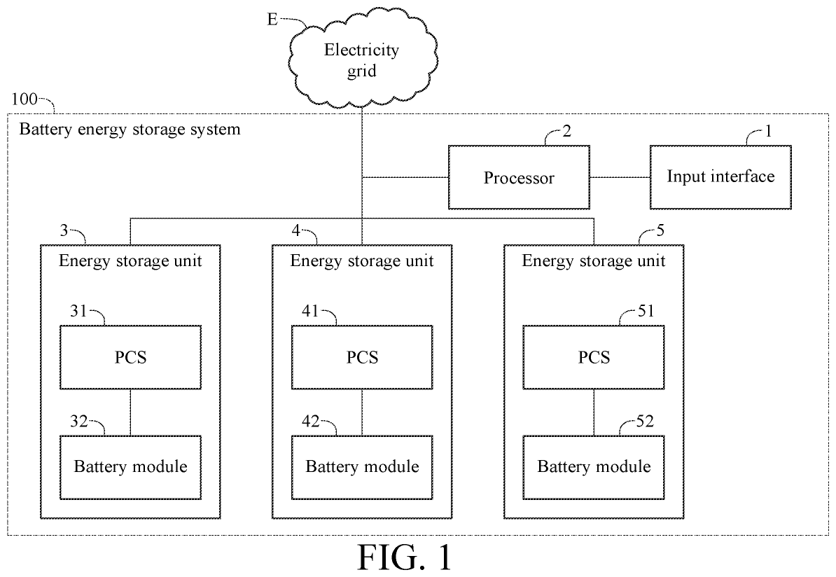

FIG. 1 is a block diagram of a BESS 100 according to an embodiment of the present disclosure. As shown in FIG. 1, the BESS 100 comprises an input interface 1, a processor 2, and a plurality of energy storage units 3, 4 and 5 connected in parallel. The BESS 100 is electrically connected to the electricity grid E for charging and discharging.

The structures of the energy storage units 3, 4 and 5 are identical basically. For example, the energy storage unit may be a rack or a container, however, the present disclosure is not limited thereof. The energy storage units 3, 4 and 5 comprise PCS 31, 41 and 51 and battery modules 32, 42, and 52. The PCS 31, 41 and 51 are electrically connected to the battery modules 32, 42, and 52 respectively, for charging or discharging their own battery module 32, 42, and 52.

The input interface 1 is configured to obtain a specified operation power of the BESS 100. In practice, the user may use the input interface 1 to enter the specified operation power of the BESS 100. It should be noted that the upper bound of the specified operation power does not greater than a sum of the input/output power of all energy storage units. In addition, the present disclosure does not limit that the implementation of the input interface 1 is a software or a hardware. For example, the input interface 1 may be an application loaded to a computing device such as a desktop computer, a laptop, or a smart phone. In another example, the input interface 1 may be a physical operation interface with a monitor and a keyboard device.

The processor 2 is electrically connected to the input interface 1 and the energy storage units 3, 4 and 5. The processor 2 is configured to perform the following steps: calculating an available operation period of each of energy storage units 3, 4 and 5 according to a maximal operation power of each of the PCS 31, 41 and 51 and a remaining power of each of the battery modules 32, 42, and 52; at least according to the available operation periods of the energy storage units 3, 4 and 5 and the specified operation power of the BESS 100, determining an operational order corresponding to the energy storage units 3, 4 and 5; and controlling the operation of each of the energy storage units 3, 4 and 5 according to the operational order.

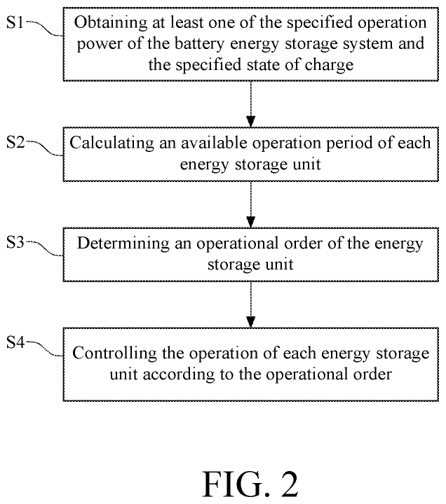

FIG. 2 is a flow chart of an operation method of the BESS according to an embodiment of the present disclosure. The operation method is applicable the BESS 100 of FIG. 1. The term “operation” represents outputting by the PCS (discharging) or inputting by the PCS (charging).

Step S1 represents “obtaining at least one of the specified operation power of the BESS and the specified SOC”. Specifically, when the BESS 100 performs the discharging operations, the specified operation power represents the overall discharging power of the BESS 100. When the BESS 100 performs the charging operation, the specified operation power is viewed as the overall charging power of the BESS 100, and the specified SOC is viewed as the expected value of the charging power of the entire BESS 100. The expected value of the charging power represents the total SOC the BESS expects to maintain, i.e., the percentage of the total energy stored by all battery modules to the total capacity of all battery modules in the BESS. For example, the SOC may be set as 60% (i.e. SOCₜₒₜₐₗ=60%), so that the BESS is capable of charging or discharging. In practice, the expected value of charging power is set according to the actual needs.

Step S2 represents “calculating an available operation period of each energy storage unit”. Specifically, when the BESS 100 performs discharging operations, the available operation period may be viewed as an available dischargeable period; and when the BESS 100 performs charging operations, the available operation period may be viewed as a remaining chargeable period.

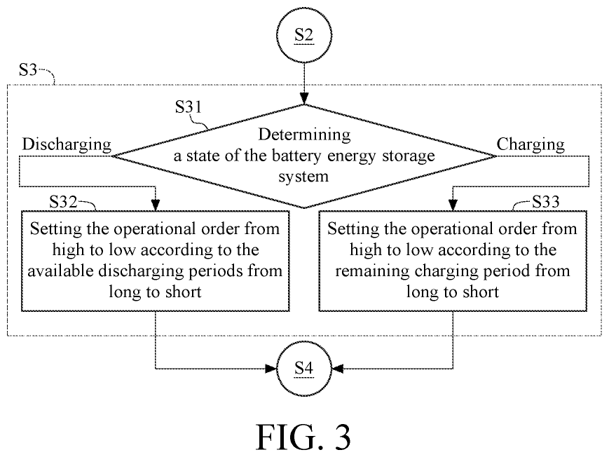

Step S3 represents “determining an operational order of the energy storage unit”. Specifically, FIG. 3 is a detailed flow chart of Step S3 in FIG. 2. Step S31 represents “determining a state of the BESS”. Specifically, when the BESS 100 is in the discharging state, the processor 2 may set high to low operational priorities for long to short dischargeable periods, respectively, as shown in Step S32. The principle of the above method is to discharge the energy storage unit with more remaining power under the premise of meeting the overall power demand of the BESS, so as to avoid the premature exhaustion of the energy storage unit with less remaining power.

On the other hand, when the BESS 100 is in the charging state, the processor 2 may set high to low operational priorities for long to short remaining chargeable periods, respectively, as shown in Step S33. The principle of the above method is to make the energy storage unit with less remaining power returning to the power enough to operate for a long time as soon as possible.

It should be noticed that when two of all available operation periods are equal, the processor 2 determines the operational order of these two energy storage units according to parameters of the two energy storage unit corresponding to two identical available operation periods, wherein the parameters comprise at least one of the maximal operation power of the PCS, the conversion efficiency of the PCS, and the State of Health (SOH) of the battery module. In other words, in addition to adjusting the operational order of charging and discharging according to the available operation period, other parameters can also be used as auxiliary references. On the whole, the processor 2 determines the operational order corresponding to these energy storage units 3, 4 and 5 at least according to multiple available operation periods of energy storage units 3, 4 and 5 and the specified operation power.

The maximal operation power described in the above may be a rated power of the PSC or a specified power defined by the user. For example, the rated power of the PCS may be 3 megawatts (MW), but the BESS may set the maximal output of the PCS as 2 MW according to actual needs, however.

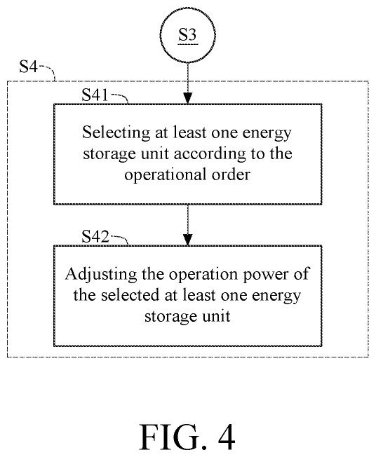

Step S4 represents “controlling the operation of each energy storage unit according to operational order”. Specifically, FIG. 4 is a detailed flow chart of Step S4 in FIG. 2. Step S41 represents “selecting at least one energy storage unit according to the operational order”, Step S42 represents “adjusting the operation power of the selected at least one energy storage unit”, wherein a sum of the selected at least one energy storage unit operation power is not smaller than the specified operation power.

In order to clearly explain the implementation details of each step of FIG. 2, FIG. 3 and FIG. 4, an example with actual values is given as follows. First, the operation method performed by the BESS 100 during discharging operation will be explained, and then the operation method performed by the BESS 100 during charging operation will be explained.

Please refer to FIG. 1. The example of the operation method performed by the BESS 100 during discharging operation will use the values listed in Table 1 below, wherein values of the maximal operation power P_{rated} of the PCS 31, 41 and 51 are 2 MW, 1 MW and 3 MW, respectively, values of the maximal stored energy of battery modules 32, 42, and 52 are 4 megawatt hour (MWh), 2 MWh and 8 MWh, respectively, and values of SOC of the battery modules 32, 42, and 52 are 50%, 20% and 40%, respectively.

TABLE 1

| Energy | | | |
|---|---|---|---|
| storage unit | P_{rated} | E_{rated} | SOC |
| 3 | 2 | 4 | 50% |
| 4 | 1 | 2 | 20% |
| 5 | 3 | 8 | 40% |

Referring to Table 1, the processor 2 may calculate the maximal operation power of the BESS 100, i.e., 2+1+3=6 MW, as well as the current stored energy of battery modules 32, 42, and 52, i.e., “4*50%=2 MWh”, “2*20%=0.4 MWh”, and “8*40%=3.2 MWh”.

Please refer to Step S1 of FIG. 2. Supposed that the user sets the specified operation power P_{tot_target} as 4 MW through the input interface 1, in Step S2, the processor 2 will calculate the available dischargeable period tₘₐₓ of each energy storage units 3, 4 and 5 according to Equation 1 below, the unit of the available dischargeable period is hour and the result is shown as Table 2 below.

$${t}_{max} = \frac{{E}_{rated} ⨯ SOC}{{P}_{r a t e d}} \qquad ( Equation 1 )$$

TABLE 2

| Energy | | | | | Operational |
|---|---|---|---|---|---|
| storage unit | P_{rated} | E_{rated} | SOC | tₘₐₓ | order |
| 3 | 2 | 4 | 50% | 1 | 2 |
| 4 | 1 | 2 | 20% | 0.4 | 3 |
| 5 | 3 | 8 | 40% | 1.067 | 1 |

Please refer to FIG. 2 and FIG. 3. In Step S3, since this example represents discharging operation, the process will move from Step S31 to Step S32 in FIG. 3. In Step S32, the processor 2 determines the operational order of energy storage units 3, 4 and 5 according to available dischargeable periods tₘₐₓ, the longer the available dischargeable period tₘₐₓ, the higher the operational priority (smaller number means higher priority). As shown in Table 2, the processor 2 selects in an order of energy storage unit 5, 3, 4.

If there are more than two energy storage units whose available dischargeable period tₘₐₓ are identical, the processor 2 may determine the operational order according to the maximal operation power P_{rated} of the PCS. If there are still two or more energy storage units with the same maximal operation power P_{rated}, the processor 2 will determine the operational order according to the conversion efficiency of the PCS or the SOH of the battery module.

Please refer to FIG. 2 and FIG. 4. In Step S41, the processor 2 first selects the energy storage unit 5 according to its operational order shown in Table 2, and calculates an accumulated power of the selected energy storage unit. The processor 2 stops the selection when the accumulated power is greater than or equal to the specified operation power P_{tot_target}, 4 MW, specified in Step S1. Regarding the example of Table 2, the accumulated power of PCS 51 and PCS 31 is shown by “3+2=5>4”, and the operation state (i.e. the “ON” state) of each of the energy storage units 3, 4 and 5 are shown as Table 3, wherein the value “1” of ON represents that the energy storage unit participates in the output operation, while the value “0” of ON represents that the energy storage unit does not participate in the output operation.

TABLE 3

| Energy | | | | | Operational | Operation |
|---|---|---|---|---|---|---|
| storage unit | P_{rated} | E_{rated} | SOC | tₘₐₓ | order | state (ON) |
| 3 | 2 | 4 | 50% | 1 | 2 | 1 |
| 4 | 1 | 2 | 20% | 0.4 | 3 | 0 |
| 5 | 3 | 8 | 40% | 1.067 | 1 | 1 |

Please refer to FIG. 4. In Step S42, the processor 2 adjusts the operation power of selected at least one energy storage unit. In the example of Table 3, since the energy storage unit 5 provides power of 3 MW, the energy storage unit 3 only needs to provide power of 1 MW for achieving the requirement that the specified operation power P_{tot_target} of 4 MW. At last, the actual output power of each of the energy storage units 3, 4 and 5 are shown as Table 4.

TABLE 4

| Energy | | | | | | | |
|---|---|---|---|---|---|---|---|
| storage | | | | | Operational | Operation | Output |
| unit | P_{rated} | E_{rated} | SOC | tₘₐₓ | order | state | power |
| 3 | 2 | 4 | 50% | 1 | 2 | 1 | 1 |
| 4 | 1 | 2 | 20% | 0.4 | 3 | 0 | 0 |
| 5 | 3 | 8 | 40% | 1.067 | 1 | 1 | 3 |

From the numbers of the examples listed in Table 1 to Table 4, it can be seen that the operation method of the BESS proposed by the present disclosure is to conditionally select specific energy storage units 5 and 3 for discharging operations. If all energy storage units 3, 4 and 5 are used to evenly distribute the specified operation power P_{tot_target} for the discharging operation, the energy storage unit 4 with the smallest SOC of the battery module is bound to exhaust all the power in advance. Once the BESS 100 is required to provide the operation power of 6 MW, the BESS 100 that has exhausted the energy of the energy storage unit 4 will not be able to meet the demand. On the other hand, the operation method of the BESS proposed by the present disclosure can avoid the above problem. In addition, for the electricity grid whose adjustment requirement occurs at any time interval (such as every second or every minute), the present disclosure can be adjusted to optimize the BESS 100 according to the requirements of the specified operation power P_{tot_target}.

Please refer to FIG. 1 and FIG. 2. The example of the operation method performed by the BESS 100 during “charging operation” will follow the values listed in Table 1. Supposed that in Step S1 of FIG. 2, the user sets the specified operation power P_{tot_target} as 2.5 MW, and sets the specified SOC_{tot_target} as 60%.

In Step S2, the processor 2 calculates the available dischargeable period tₘₐₓ of each of the energy storage units 3, 4 and 5, according to Equation 1. Moreover, the processor 2 further uses Equation 2 below to calculate the required target charging time t_{target} that each of the PCS 31, 41 and 51 starts charging with the maximal operating power from the SOC of 0% until the battery modules 32, 42, and 52 meet the specified SOC_{tot_target}.

$${t}_{target} = \frac{{E}_{rated} ⨯ SO {C}_{target}}{{P}_{r a t e d}} \qquad ( Equation 2 )$$

The following Table 5 lists the target charging time t_{target} and the remaining chargeable period Δt of each of the energy storage units 3, 4, and 5. The remaining chargeable period Δt is a difference value between the target charging time t_{target} and the available dischargeable period tₘₐₓ.

TABLE 5

| Energy | | | | | | | Operational |
|---|---|---|---|---|---|---|---|
| storage unit | P_{rated} | E_{rated} | SOC | tₘₐₓ | t_{target} | Δt | order |
| 3 | 2 | 4 | 50% | 1 | 1.2 | 0.2 | 3 |
| 4 | 1 | 2 | 20% | 0.4 | 1.2 | 0.8 | 1 |
| 5 | 3 | 8 | 40% | 1.067 | 1.6 | 0.537 | 2 |

Please refer to FIG. 2 and FIG. 3. In Step S3, since this example represents charging operation, the process will move from Step S31 to Step S33 of FIG. 3. In Step S33, the processor 2 firstly determines the operational order of the energy storage units 3, 4 and 5 according to the remaining chargeable periods Δt, the longer the remaining chargeable period Δt, the higher the operational priority. As shown in Table 5, the processor 2 may select in an order of the energy storage unit 4, the energy storage unit 5, and the energy storage unit 3.

Supposed that there are more than two energy storage units whose remaining chargeable periods Δt are identical, the processor 2 will determines the operational order according to the maximal operation power P_{rated} of the PCS. If there are still two or more energy storage units with the same maximal operation power P_{rated}, the processor 2 will determine the operational order according to the conversion efficiency of the PCS or the SOH of the battery module.

Please refer to FIG. 2 and FIG. 4. In Step S41, the processor 2 first selects the energy storage unit 4 according to its operational order shown in Table 5, and calculates an accumulated power of the selected energy storage unit. The processor 2 stops the selection when the accumulated power is greater than or equal to the specified operation power P_{tot_target}, 2.5 MW, specified in Step S1. Regarding the example of Table 5, the accumulated power of PCS 41 and PCS 51 is “1+3=4>2.5”, therefore, the operation state ON of each of the energy storage units 3, 4 and 5 are show as Table 6, wherein the value “1” of ON represents that the energy storage unit participates the output operation, while the value “0” of ON represents that the energy storage unit does not participate the output operation.

TABLE 6

| Energy | | | | | | | Operational | Operation | Output |
|---|---|---|---|---|---|---|---|---|---|
| storage unit | P_{rated} | E_{rated} | SOC | tₘₐₓ | t_{target} | Δt | order | state ON | power |
| 3 | 2 | 4 | 50% | 1 | 1.2 | 0.2 | 3 | 0 | 0 |
| 4 | 1 | 2 | 20% | 0.4 | 1.2 | 0.8 | 1 | 1 | 1 |
| 5 | 3 | 8 | 40% | 1.067 | 1.6 | 0.537 | 2 | 1 | 1.5 |

Please refer to FIG. 4. In Step S42, the processor 2 adjusts the operation power of selected at least one energy storage unit. In the example of Table 6, since the energy storage unit 4 provides power of 1 MW, the energy storage unit 5 only needs to provide power of 1.5 MW for achieving the requirement that the specified operation power P_{tot_target} of 2.5 MW. At last, the actual output power of each of the energy storage units 3, 4 and 5 are shown as Table 6.

From the numbers of the examples listed in Table 5 to Table 6, it can be seen that the operation method of the BESS proposed by the present disclosure is to conditionally select specific energy storage units 4 and 5 for charging operation. If all energy storage units 3, 4 and 5 perform the charging operations concurrently, the overall charging efficiency will be affected by battery modules with lower SOC in an undesired way. Once the BESS 100 is required to provide 6 MW of operation power, the power supply time of the BESS that uses all energy storage units 3, 4 and 5 to charge at the same time is less than the power supply time of the BESS 100 that uses the operation method proposed by the present disclosure. In addition, for the adjustment requirements of the electricity grid at any time interval (such as every second or every minute), the present disclosure can optimize the BESS 100 according to the requirements of the specified SOC_{tot_target}, and repeated correction of the power dispatch can make the BESS 100 maintain the state of maximal output time with maximum power.

In view of the above, the present disclosure provides a BESS and an operation method thereof. Through the optimization of the input/output power configuration, the present disclosure can avoid the following situation: some energy storage units are fully discharged or fully charged in advance since each battery module has a different SOC, this situation will reduce the overall maximal input/output capacity of the BESS. The present disclosure allows the BESS to extend the duration of maximal power input/output, and to meet the requirements of the specified operation power or the specified SOC.

The present disclosure is applicable to energy storage application fields with rapidly changing output, such as automatic frequency adjustment auxiliary services, applications for smoothing the output of renewable energy, and can also be applied to general energy storage application fields referred to as “peak cut” that adjusts the power load. The present disclosure can be implemented to provide high technical feasibility, easy commercialization and low cost without using complex statistical analytical methods and related software.

What is claimed is:

1. An operation method of Battery Energy Storage System (BESS) applicable to a BESS, wherein the BESS comprises a plurality of energy storage units connected in parallel and a processor, each of the plurality of energy storage units comprises a Power Conversion System (PCS) and a battery module, and the operation method comprises following operations performed by the processor:
obtaining at least one of a specified operation power and a specified State of Charge (SOC) of the BESS;
calculating an available operation period of each of the plurality of the energy storage units according to a maximal operation power of the PCS of each of the plurality of energy storage units and a remaining power of each of the battery module of each of the plurality of energy storage units;
determining an operational order corresponding to the plurality of energy storage units at least according to the available operation period of each of the plurality of energy storage units and the specified operation power of the BESS; and
controlling an operation of each of the plurality of energy storage units according to the operational order.

2. The operation method of BESS of claim 1, wherein controlling the operation of each of the plurality of energy storage unit according to the operational order comprises:
selecting at least one of the plurality of energy storage units according to the operational order; and
adjusting an operation power of selected said at least one energy storage unit, wherein a sum of the operation power of selected said at least one energy storage unit is not smaller than the specified operation power.

3. The operation method of BESS of claim 1, wherein determining the operational order corresponding to the plurality of energy storage units at least according to the plurality of available operation periods of the plurality of energy storage units and the specified operation power comprises:
when the BESS is in a discharging state, each of the plurality of available operation periods is an available dischargeable period, and the processor sets a high operational order to a maximal one of the plurality of available dischargeable periods, and sets a low operational order to a minimal one of the plurality of available dischargeable periods; and
when two of the plurality of available dischargeable periods are equal, the processor determines the operational order of the two energy storage units according to two parameters of the two energy storage units corresponding to the two available dischargeable periods.

4. The operation method of BESS of claim 3, wherein the parameter of each of the plurality of energy storage units comprises one of a maximal operation power of the PCS, a conversion efficiency of the PCS, and a State of Health (SOH) of the battery module.

5. The operation method of BESS of claim 1, wherein determining the operational order corresponding to the plurality of energy storage units at least according to the plurality of available operation periods of the plurality of energy storage units and the specified operation power comprises:
when the BESS is in a charging state, each of the plurality of available operation period is a remaining chargeable period, and the processor sets a high operational order to a maximal one of the plurality of remaining chargeable periods, and sets a low operational order to a minimal one of the plurality of remaining chargeable periods; and
when two of the plurality of remaining chargeable periods are equal, the processor determines the operational order of the two energy storage units according to two parameters of the two energy storage units corresponding to the two remaining chargeable periods.

6. The operation method of BESS of claim 5, wherein the parameter of each of the plurality of energy storage units comprises one of a maximal operation power of the PCS, a conversion efficiency of the PCS, and a State of Health (SOH) of the battery module.

7. A BESS comprising:
an input interface configured to obtain a specified operation power of the BESS;
a plurality of energy storage units connected in parallel, wherein each of the plurality of energy storage unit comprises a PCS and a battery module, and the PCS is electrically connected to the battery module for charging the battery module or discharging the battery module; and
a processor electrically connected to the input interface and the plurality of energy storage unit, wherein the processor is configured to perform following operations:
calculating an available operation period of each of the plurality of the energy storage units according to a maximal operation power of each of the plurality of PCS and a remaining power of each of the plurality of battery module;
determining an operational order corresponding to the plurality of energy storage units at least according to the available operation period of each of the plurality of energy storage units and the specified operation power of the BESS; and
controlling an operation of each of the plurality of energy storage units according to the operational order.

8. The BESS of claim 7, wherein the operation of controlling the operation of each of the plurality of energy storage units according to the operational order by the processor comprises:
selecting at least one of the plurality of energy storage units according to the operational order; and
adjusting an operation power of selected said at least one energy storage unit, wherein a sum of the operation power of selected said at least one energy storage unit is not smaller than the specified operation power.

9. The BESS of claim 7, wherein determining the operational order corresponding to the plurality of energy storage units at least according to the plurality of available operation periods of the plurality of energy storage units and the specified operation power comprises:
when the BESS is in a discharging state, each of the plurality of available operation periods is an available dischargeable period, and the processor sets a high operational order to a maximal one of the plurality of available dischargeable periods, and sets a low operational order to a minimal one of the plurality of available dischargeable periods; and
when two of the plurality of available dischargeable periods are equal, the processor determines the operational order of the two energy storage units according to two parameters of the two energy storage units corresponding to the two available dischargeable periods.

10. The BESS of claim 9, wherein the parameter of each of the plurality of energy storage units comprises one of a maximal operation power of the PCS, a conversion efficiency of the PCS, and a SOH of the battery module.

11. The BESS of claim 7, wherein determining the operational order corresponding to the plurality of energy storage units at least according to the plurality of available operation periods of the plurality of energy storage units and the specified operation power comprises:
when the BESS is in a charging state, each of the plurality of available operation period is a remaining chargeable period, and the processor sets a high operational order to a maximal one of the plurality of remaining chargeable periods, and sets a low operational order to a minimal one of the plurality of remaining chargeable periods; and
when two of the plurality of remaining chargeable periods are equal, the processor determines the operational order of the two energy storage units according to two parameters of the two energy storage units corresponding to the two remaining chargeable periods.

12. The BESS of claim 11, wherein the parameter of each of the plurality of energy storage units comprises one of a maximal operation power of the PCS, a conversion efficiency of the PCS, and a SOH of the battery module.
